(19) United States
(12) Patent Application Publication
(10) Pub. No.: US 2023/0352574 A1
(43) Pub. Date: Nov. 2, 2023

(54) ENHANCEMENT MODE HIGH-ELECTRON-MOBILITY TRANSISTOR HAVING N-I-P SEMICONDUCTOR JUNCTION STRUCTURE AND APPLICATIONS THEREOF

(71) Applicant: Unikorn Semiconductor Corporation, Hsinchu (TW)

(72) Inventors: Shang-Ju Tu, Tainan (TW); Tien Ching Feng, Taichung (TW); Chia-Cheng Liu, Hsinchu (TW); Ming-Chin Chen, Kaohsiung (TW); Yu-Jen Liu, Taichung (TW); Chung-Chih Tsai, Taichung (TW); Tsung-Cheng Chang, Taichung (TW); Ya-Yu Yang, Toufen City (TW)

(21) Appl. No.: 17/732,800

(22) Filed: Apr. 29, 2022

(51) Int. Cl. H01L 29/778; H01L 29/207; H01L 29/20; H01L 29/06

(52) U.S. Cl. CPC H01L 29/7787; H01L 29/207; H01L 29/2003; H01L 29/0607

(57) ABSTRACT

A semiconductor component is provided in the form of an enhancement mode high-electron-mobility transistor having an n-i-p semiconductor junction epitaxial structure. The semiconductor component includes: a channel layer and a barrier layer formed on the channel layer. A two-dimensional electron gas (2DEG) is formed in the channel layer adjacent to an interface between the channel layer and the barrier layer. A gate electrode is disposed on the barrier layer. A semiconductor junction structure is disposed and sandwiched between the gate electrode and the barrier layer. The semiconductor junction structure includes a first region doped with a first dopant and in direct contact with the gate electrode, a second region doped with a second dopant different from the first dopant, and a third region being unintentionally doped and sandwiched between the first region and the second region. The semiconductor junction structure depletes a portion of the 2DEG thereunder.

### FIELD

The disclosure relates generally to field-effect transistor (FET) technology, and more particularly to an enhancement mode high-electron-mobility transistor (E-HEMT) and applications thereof.

### BACKGROUND

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

A high-electron-mobility transistor (HEMT) is a field-effect transistor (FET) incorporating a junction between two materials with different band gaps (i.e., a heterojunction) as the channel instead of a doped region, as is generally the case for a metal-oxide-semiconductor FET (MOSFET). The HEMT is also known as a heterostructure FET (HFET) or modulation-doped FET (MODFET). Like other types of FETs, HEMTs are commonly used in integrated circuits as digital on-off switches. HEMT transistors may operate at higher frequencies than ordinary transistors. However, there are some deficiencies in the conventional HEMTs.

There are various types of HEMTs. For instance, different types of HEMTs may include, without being limited thereto, a depletion mode HEMT (D-HEMT) a p-type GaN (P-GaN) enhancement mode HEMT (E-HEMT), and a recess gate metal-insulator gate (MIS) E-HEMT. All of these different types of HEMTs may include a channel layer, a barrier layer, a source electrode, a drain electrode, a gate electrode and a passivation layer. However, the corresponding structural configuration between the gate electrode and the barrier layer may be different. For example, in the D-HEMT, the gate electrode is disposed on the barrier layer, forming a Schottky contact between the gate electrode and the barrier layer. Further, a two-dimensional electron gas (2DEG) is formed in the channel layer, and the source electrode and the drain electrode are disposed above the 2DEG, thus forming the D-HEMT. In comparison, the P-GaN E-HEMT includes a p-type GaN layer, which is provided between the gate electrode and the barrier layer, such that the gate electrode is not in direct contact with the barrier layer, and that the p-type GaN layer depletes a portion of the 2DEG thereunder, such that a gap area exists in the 2DEG right below the p-type GaN layer. Moreover, in the recess gate MIS E-HEMT, a via is formed in the barrier layer and the top portion of the channel layer, such that the gate electrode may extend downward into the via, and correspondingly, a gap area caused by the formation of the via exists in the 2DEG.

In comparison to the D-HEMT, the P-GaN E-HEMT and the recess gate MIS E-HEMT may have the characteristics of having a positive threshold voltage Vₜₕ and a lower gate current I_{g} when the gate voltage V_{gs} is greater than 0. However, there are certain limitations in the P-GaN E-HEMT and the MIS E-HEMT performance. Specifically, at the same gate voltage, in order to get a lower gate current I_{g}, the P-GaN E-HEMT may have to sacrificially reduce the currents I_{ds}, and the currents I_{ds} and I_{g} may be further reduced in the MIS E-HEMT structure. In order to increase the currents I_{ds} of P-GaN E-HEMT, the threshold voltage Vₜₕ of the P-GaN E-HEMT is generally at a range of about 1.2 V to 1.7 V, which is relatively low, such that the components of the P-GaN E-HEMT may be easily affected by the voltage surge of the system circuits to turn on at unwanted or abnormal scenarios. In order to increase the threshold voltage Vₜₕ, the polarization near the channel layer and the barrier layer may have to be correspondingly reduced, which may cause the current I_{ds} to be reduced, thus resulting in a relatively high resistance Ron. In addition, the reduction of the polarization is subject to certain limitations when the size of the transistor is relatively small, which may limit a maximum overall thickness of the chip. Further, the surface of the p-type GaN layer may be easily damaged during the process of forming or etching the passivation layer thereon. Moreover, the thickness of the p-type GaN layer may be significant (i.e., 50 nm or more) to be effective, and the concentration of the p-type dopant in the p-type GaN layer may reach 5E18 cm⁻³. Due to the use of the p-type GaN layer, there may be I_{g} current leakage, and to reduce the current leakage problem, the doping concentration of the p-type GaN layer may be reduced, which may further reduce the threshold voltage Vₜₕ.

Therefore, a heretofore unaddressed need exists in the art to address the aforementioned deficiencies and inadequacies.

### SUMMARY

One aspect of the disclosure relates to a semiconductor component, which includes: a channel layer; a barrier layer, formed on the channel layer; a two-dimensional electron gas (2DEG), formed in the channel layer adjacent to an interface between the channel layer and the barrier layer; a gate electrode disposed on the barrier layer; a semiconductor junction structure, disposed and sandwiched between the gate electrode and the barrier layer; and a source electrode and a drain electrode, disposed at two sides of the gate electrode. The semiconductor junction structure includes: a first region doped with a first dopant and in direct contact with the gate electrode; a second region doped with a second dopant different from the first dopant; and a third region being unintentionally doped and sandwiched between the first region and the second region. The semiconductor junction structure depletes a portion of the 2DEG thereunder.

In certain embodiments, the semiconductor component is an enhancement mode high-electron-mobility transistor (E-HEMT).

In certain embodiments, the semiconductor component has a threshold voltage greater than 2.5 V.

In certain embodiments, the third region forms a complete depletion region in the semiconductor junction structure.

In certain embodiments, a contact between the first region and the gate electrode is a Schottky contact or an Ohmic contact.

In certain embodiments, the semiconductor junction structure is an n-i-p junction structure, the first region is an n-type nitride region, and the second region is a p-type nitride region.

In certain embodiments, the first dopant includes silicon (Si) or oxygen, and the second dopant includes magnesium (Mg), calcium (Ca), zinc (Zn), beryllium (Be) or carbon (C).

In certain embodiments, the first region includes the second dopant.

In certain embodiments, each of the first, second and third region includes a nitride semiconductor material selected from a group consisting of GaN, AlGaN and AlN.

In certain embodiments, a thickness of the second region is greater than a thickness of the first region and a thickness of the third region.

In certain embodiments, a thickness of the first region is in a range of 5-100 nm.

In certain embodiments, the thickness of the first region is in a range of 20-30 nm.

In certain embodiments, a thickness of the second region is in a range of 50-200 nm.

In certain embodiments, the thickness of the second region is in a range of 55-75 nm.

In certain embodiments, a thickness of the third region is in a range of 1-50 nm.

In certain embodiments, the thickness of the third region is in a range of 5-15 nm.

In certain embodiments, a concentration of the first dopant of the first region is in a range of 5E16 to 5E19 cm⁻³, and a concentration of the second dopant of the second region is in a range of 1E18 to 1E20 cm⁻³.

In certain embodiments, the semiconductor component further includes: a passivation layer located between the gate electrode, the source electrode and the drain electrode, and covering the semiconductor junction structure and the barrier layer.

Another aspect of the disclosure relates to an electronic switch, which includes at least one of the semiconductor components as discussed above.

A further aspect of the disclosure relates to an electronic device, which includes at least one of the semiconductor components as discussed above.

These and other aspects of the disclosure will become apparent from the following description of the preferred embodiment taken in conjunction with the following drawings, although variations and modifications therein may be effected without departing from the spirit and scope of the novel concepts of the disclosure.

### BRIEF DESCRIPTION OF THE DRAWINGS

The accompanying drawings illustrate one or more embodiments of the disclosure and together with the written description, serve to explain the principles of the disclosure. Wherever possible, the same reference numbers are used throughout the drawings to refer to the same or like elements of an embodiment, and wherein:

FIG. 1A schematically shows an enhancement mode high-electron-mobility transistor (E-HEMT) according to an embodiment of the disclosure.

FIG. 1B schematically shows detailed structures of the E-HEMT of FIG. 1A.

FIG. 2 shows the comparison of a p-n junction structure and a p-i-n junction structure according to certain embodiments of the disclosure.

FIG. 3 schematically shows the junction capacitance according to certain embodiments of the disclosure.

FIG. 4 schematically shows a p-GaN E-HEMT according to a comparative example of the disclosure.

FIG. 5 shows the drain current-to-gate voltage (I_{d}-Vg) curve of the p-GaN E-HEMT according to a comparative example and an E-HEMT according to certain embodiment of the disclosure respectively.

FIG. 6 shows comparisons of the leakages of gate current I_{g} between the p-GaN E-HEMT according to a comparative example and the E-HEMT according to certain embodiments of the disclosure.

FIG. 7A shows the capacitance-to-voltage (CV) curves of a p-GaN E-HEMT at 100K Hz and 1M Hz respectively according to a comparative example.

FIG. 7B shows the capacitance-to-voltage (CV) curves of the E-HEMT according to an embodiment of the disclosure.

### DETAILED DESCRIPTION OF THE DISCLOSURE

The present disclosure will now be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

The terms used in this specification generally have their ordinary meanings in the art, within the context of the invention, and in the specific context where each term is used. Certain terms that are used to describe the invention are discussed below, or elsewhere in the specification, to provide additional guidance to the practitioner regarding the description of the invention. For convenience, certain terms may be highlighted, for example using italics and/or quotation marks. The use of highlighting has no influence on the scope and meaning of a term; the scope and meaning of a term is the same, in the same context, whether or not it is highlighted. It will be appreciated that same thing can be said in more than one way. Consequently, alternative language and synonyms may be used for any one or more of the terms discussed herein, nor is any special significance to be placed upon whether or not a term is elaborated or discussed herein. Synonyms for certain terms are provided. A recital of one or more synonyms does not exclude the use of other synonyms. The use of examples anywhere in this specification including examples of any terms discussed herein is illustrative only, and in no way limits the scope and meaning of the invention or of any exemplified term. Likewise, the invention is not limited to various embodiments given in this specification.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising”, or “includes” and/or “including” or “has” and/or “having” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom”, “upper” or “top”, and “left” and “right”, may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper”, depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As used herein, “around”, “about” or “approximately” shall generally mean within 20 percent, preferably within 10 percent, and more preferably within 5 percent of a given value or range. Numerical quantities given herein are approximate, meaning that the term “around”, “about” or “approximately” can be inferred if not expressly stated.

As used herein, the term “doping” refers to the intentional introduction of impurities into an intrinsic semiconductor layer for the purpose of modulating its electrical optical and structural properties, and the terms “doped semiconductor material” or “doped layer” refer to the semiconductor material or the layer being performed with a doping process. In comparison, as used herein, the terms “unintentionally doped semiconductor material” or “unintentionally doped region” refer to the semiconductor material or the region not intentionally introduced with the impurities, or not being performed with a doping process. Herein, the doping process, for example, includes intentionally rising the temperature of the reactor with an interrupting growth process after forming the intrinsic semiconductor layer on a doped layer, and the dopant in the doped layer is diffused to the intrinsic semiconductor layer. In other words, an “unintentionally doped” semiconductor material is a semiconductor material not being performed with a doping process.

The description will be made as to the embodiments of the present disclosure in conjunction with the accompanying drawings. In accordance with the purposes of this disclosure, as embodied and broadly described herein, this disclosure, in certain aspects, relates to an enhancement mode field-effect transistor having an n-i-p gate epitaxial structure and applications thereof.

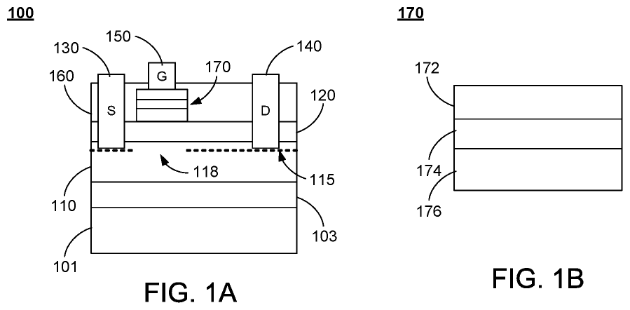

One aspect of the disclosure relates to a semiconductor component in the form of an enhancement mode (normally off) field-effect transistor having an n-i-p gate epitaxial structure. For example, FIG. 1A schematically shows an enhancement mode high-electron-mobility transistor (E-HEMT) 100 having an n-i-p gate epitaxial structure according to certain embodiments of the disclosure. Specifically, as shown in FIG. 1A, the E-HEMT 100 includes a substrate 101, a buffer structure 103, a channel layer 110, a barrier layer 120, a source electrode 130, a drain electrode 140, a gate electrode 150, and a semiconductor junction structure 170 formed between the barrier layer 120 and the gate electrode 150.

The material of the substrate 101 includes semiconductor or oxide. The semiconductor layers are formed on the substrate 101 by suitable methods such as metal-organic chemical vapor deposition (MOCVD), molecular beam epitaxy (MBE), hydride vapor epitaxy (HVPE), liquid phase epitaxy (LPE) or atomic layer deposition (ALD). The semiconductor may include silicon (Si), gallium nitride (GaN), silicon carbide (SiC), or gallium arsenide (GaAs). The oxide may include sapphire. In addition, the substrate 101 can be a conductive substrate or an insulating substrate. The material of the conductive substrate may include silicon (Si), gallium nitride (GaN), or gallium arsenide (GaAs). The material of the insulating substrate may include sapphire or combinatorial material such as silicon on insulator (SOI). The substrate 101 can be selectively doped with dopants to change its conductivity to form a conductive substrate or a non-conductive substrate. For a silicon (Si) substrate, the dopant can include boron (B), arsenic (As) or phosphorus (P). In one embodiment, the substrate 101 is a silicon substrate with a thickness of 1000-1200 μm. A nucleation layer (not shown in FIG. 1A) is formed between the substrate 101 and the buffer structure 103 and has a thickness of tens of nanometers or hundreds of nanometers. The nucleation layer may reduce the lattice mismatch between the substrate 101 and the buffer structure 103. The nucleation layer may include III-V group semiconductor material, such as aluminum nitride (AlN), gallium nitride (GaN), or aluminum gallium nitride (AlGaN). The buffer structure 103 is located above the nucleation layer and has a thickness of several micrometers or tens of micrometers. The buffer structure 103 may include III-V group material and can be used to lessen lattice dislocations. In the present embodiment, the buffer structure 103 can be a single-layer structure or a multi-layer structure. In one embodiment, the single-layer structure may include a gradient composition. One element of the material of the single-layer structure is changed gradually along the growth direction. In one embodiment, the multi-layer structure may include a superlattice or a plurality of layers alternately laminated. The buffer structure 103 may include III-V group semiconductor materials, such as AlN, GaN, or AlGaN and can be doped. For example, the buffer structure 103 may include the dopant of carbon (C) and/or iron (Fe) and the concentration of the dopant can be gradually changed or remains constant along the growth direction.

The channel layer 110 is disposed on the buffer structure 103 and has a first bandgap. The barrier layer 120 is disposed on the channel layer 110 and has a second bandgap that is higher than the first bandgap. In other words, the materials of the channel layer 110 and the barrier layer 120 are different. In the present embodiment, the channel layer 110 and the barrier layer 120 may include nitride semiconductor such as GaN, AlN, InGaN, AlGaN, or AlInGaN. In one embodiment, the channel layer 110 includes GaN and the barrier layer 120 includes AlGaN. Spontaneous polarization occurs in the channel layer 110 and the barrier layer 120. Furthermore, piezoelectric polarization occurs in the channel layer 110 and the barrier layer 120 due to stress caused by a difference in lattice constants between the different nitride semiconductors. Both the spontaneous polarization and the piezoelectric polarization bend the bandgaps of the channel layer 110 and the barrier layer 120 so that a two-dimensional electron gas (2DEG) 115 is formed in the channel layer 110 near an interface between the channel layer 110 and the barrier layer 120. In one embodiment, the channel layer 110 and the barrier layer 120 can be undoped or doped. For example, the channel layer 110 and the barrier layer 120 can be doped with silicon (Si) and the concentration of the 2DEG 115 can be adjusted in accordance with the doping concentration. In one embodiment, the barrier layer 120 includes multiple sub-barrier layers. For example, the barrier layer 120 includes an AlGaN sub-layer on the channel layers, and an AlN sub-layer on or below the AlGaN sub-layer.

The gate electrode 150 is disposed on the barrier layer 120, and the source electrode 130 and the drain electrode 140 are disposed at two sides of the gate electrode 150 at intervals, such that the source electrode 130 and the drain electrode 140 are respectively in direct contact with the channel layer 110 and not in direct contact with the gate electrode 150. In another embodiment, the source electrode 130 and the drain electrode 140 are respectively in direct contact with the barrier layer 120. The material of the drain electrode 140 and the source electrode 130 can be selected from silver (Ag), aluminum (Al), tungsten (W), tantalum (Ta), cadmium (Cd), zirconium (Zr), titanium (Ti), and an alloy or a combination thereof. The material of the gate electrode 150 includes conductive material, such as metal or metal compound. For example, the metal can be selected from gold (Au), nickel (Ni), platinum (Pt), palladium (Pd), iridium (Ir), titanium (Ti), chromium (Cr), tungsten (W), aluminum (Al), copper (Cu), silver (Ag), and an alloy or a combination thereof. The metal compound may include any one of compounds of the above metals, such as titanium nitride (TiN), tungsten titanium (TiW). The semiconductor junction structure 170 is provided between the gate electrode 150 and the barrier layer 120, such that the gate electrode 150 is not in direct contact with the barrier layer 120. In one embodiment, the E-HEMT 100 includes a passivation layer 160. The passivation layer 160 is disposed between the source electrode 130, the drain electrode 140, the gate electrode 150 and the semiconductor junction structure 170, and covers the semiconductor junction structure 170 and the barrier layer 120 to provide passivation therebetween. The 2DEG 115 is formed in the channel layer 110, such that the source electrode 130 and the drain electrode 140 are disposed above the 2DEG 115. The semiconductor junction structure 170 depletes a portion of the 2DEG 115 thereunder, such that a depletion area 118 exists in the 2DEG 115 right below the semiconductor junction structure 170 and the channel layer 110 is non-conducting with no gate bias. Further, the contact between the gate electrode 150 and the semiconductor junction structure 170 can be a Schottky contact or an Ohmic contact. Both the contacts between drain electrode 140 and the channel layer 110 and the source electrode 130 and the channel layer 110 can be Ohmic contacts.

FIG. 1B schematically shows detailed structures of the semiconductor junction structure 170 of FIG. 1A. As shown in FIG. 1B, the semiconductor junction structure 170 can include three regions, including a first region 172 at its top facing the gate electrode 150, a second region 176 at its bottom facing the barrier layer 120, and a third region 174 sandwiched between the first region 172 and the second region 174. Specifically, the first region 172 can be in direct contact with the gate electrode 150 (and as discussed above, the contact between the first region 172 and the gate electrode 150 can be a Schottky contact or an Ohmic contact). The semiconductor junction structure 170 may be formed by nitride semiconductor such as AlₓIn_{y}Ga_{(1-x-y)}N, wherein 0≤x<1, 0≤y<1, and 0≤x+y<1. Further, the first region 172 is doped with a first dopant) and the second region 176 is doped with a second dopant having conductivity type different from that of the first dopant. In one embodiment, the first dopant includes n-type dopant and the second dopant includes p-type dopant. In certain embodiments, the n-type dopant may include silicon (Si), and the p-type dopant may include magnesium (Mg), iron (Fe), zinc (Zn), beryllium (Be), carbon (C) or other suitable p-type dopants. In the embodiment, the n-type dopant is Si, and the p-type dopant is Mg. The third region 174, which is an intermediate region sandwiched between the first region 172 and the second region 176. In one embodiment of the epitaxial growth process, the source of the III-V elements and the source of the p-type dopant are turned on and introduced into the reactor to form the second region 176. After finishing growing the second region 176, the source of the p-type dopant is closed, and the source of the III-V elements are introduced into the reactor continuously to form the third region 174. Then the source of the n-type dopant is turned on and introduced into the reactor and react with the III-V elements to form the first region 172. In one embodiment, the third region is undoped. In one embodiment, during growing the first region 172, the p-type dopant and n-type dopant may be diffused into the third region 174 caused by the growth temperature of the first region 172, which is not a doping process of intentionally rising the temperature without epitaxial growth. After that, the third region 174 includes slightly impurities of the p-type dopant and/or the n-type dopant. In these ways, the third region 174 is unintentionally doped (i.e., undoped or not intentionally doped) with the p-type dopant and/or the n-type dopant. The semiconductor junction structure 70 may be formed as an n-i-p junction structure, where the first region 172 is an n-type region, the second region 176 is a p-type region, and the third region 174 is an intermediate region. In one embodiment, the concentration of the p-dopant and the n-dopant in the intermediate region is lower than that of the p-dopant in the second region 176 and is lower than that of the n-dopant in the first region 172. In one embodiment, the intermediate region is unintentionally doped region. In one embodiment, the dopant concentration in the intermediate region is lower enough and the intermediate region performs as an intrinsic semiconductor. For example, the dopant concentration of the p-dopant and the n-dopant in the intermediate region may be lower than 1E16 cm⁻³. In certain embodiments, the third region 174 forms a complete depletion region in the semiconductor junction structure 170.

The first region 172, the second region 176 and a third region 174 can be formed by the same nitride semiconductor. For example, the first region 172 includes n-GaN, the second region 176 includes p-GaN and the third region 174 includes GaN which is unintentionally doped. In another embodiment, any one of the first region 172, the second region 176 and a third region 174 can be formed by different nitride semiconductor. For example, the second region 176 includes p-GaN, the first region 172 includes n-Alₓ₁Ga₍₁₋ₓ₁₎N and the third region 174 includes Alₓ₂Ga₍₁₋ₓ₂₎N which is unintentionally doped, wherein 0<x1<1, 0<x2<1 and x1 can be equal to or different from x2. The third region 174 which includes AlGaN has wide bandgap and can suppress current leakage, and the first region 172 which includes AlGaN is suitable for forming Schottky contact with the gate electrode 150. For example, the second region 176 includes p-GaN, the first region 172 includes n-Inₓ₁Ga₍₁₋ₓ₁₎N and the third region 174 includes Alₓ₂Ga₍₁₋ₓ₂₎N which is unintentionally doped, wherein 0<x1<1 and 0<x2<1. The first region 172 which includes InGaN is suitable for forming Ohmic contact with the gate electrode 150. In another embodiment, the third region 174 can be formed by different nitride semiconductor. For example, a first portion of the third region 174 near the first region 172 and a second portion of the third region 174 near the second region 176 include different composition.

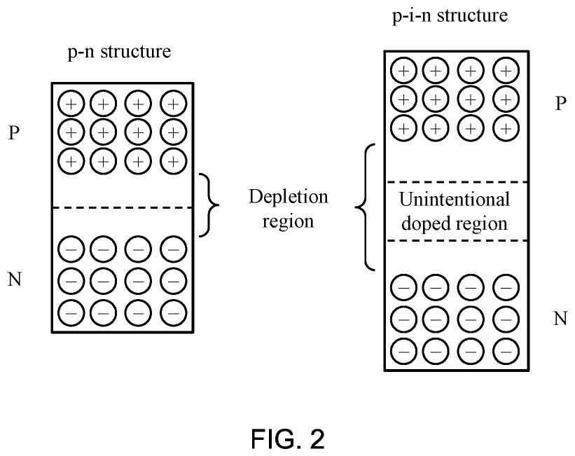

The n-i-p junction structure is a diode structure with an intermediate region (such as the third region 174) between a p-type semiconductor region (such as the second region 176) and an n-type semiconductor region (such as the first region 172). FIG. 2 shows the comparison of a n-p junction structure and a n-i-p junction structure according to certain embodiments of the disclosure. As shown in FIG. 2, due to the existence of the unintentionally doped region in the n-i-p junction structure, the n-i-p junction structure has a much wider depletion region than the n-p junction structure.

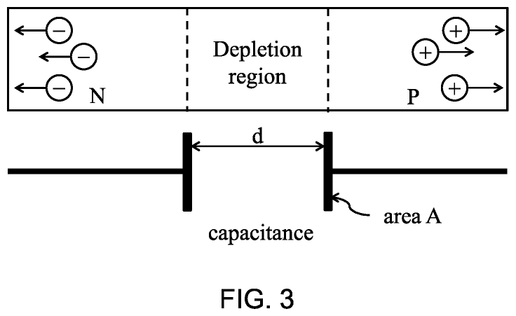

FIG. 3 schematically shows the junction capacitance caused by the depletion region of a diode structure according to certain embodiments of the disclosure. As shown in FIG. 3, in a diode, the junction capacitance thereof is determined by the size of the depletion region. Specifically, the capacitance Ct can be represented as:

$${C}_{t} = ε \frac{A}{d}$$

wherein d is the distance or the thickness of the depletion region and A is the area of the depletion region.

Thus, the n-i-p junction structure, which has a much wider depletion region than the n-p junction structure, may correspondingly have a larger junction resistance and alower junction capacitance, thus making the n-i-p junction structure suitable for attenuators, fast switches, photodetectors, and high-voltage power electronics applications.

In certain embodiments, a thickness of the second region 176 is greater than a thickness of the first region 172 and a thickness of the third region 174. In certain exemplary embodiments, a thickness of the first region 172 may be in a range of 5-100 nm, a thickness of the second region 176 may be in a range of 50-200 nm, and a thickness of the third region 174 may be in a range of 1-50 nm. If the thickness of the third region 174 is smaller than 1 nm, the third region 174 may not effectively formed. If the thickness of the third region 174 is larger than 50 nm, the switching speed of the transistor may slow and the loss may increase. In certain embodiments, the thickness of the first region 172 may be in a range of 20-30 nm, the thickness of the second region 176 may be in a range of 55-75 nm, and the thickness of the third region 174 may be in a range of 5-15 nm. For example, the thickness of the first region 172 may be about 25 nm, the thickness of the second region 176 may be about 65 nm, and the thickness of the third region 174 may be about 10 nm.

In certain embodiments, a concentration of the first dopant of the first region 172 is in a range of 5E16 to 5E19 cm⁻³, and a concentration of the second dopant of the second region 176 is in a range of 1E18 to 1E20 cm⁻³. The electron concentration of the first region 172 is higher than the hole concentration of the second region 176. In certain embodiments, the electron concentration in the first region 172 is in a range of 5E17 to 1E19 cm⁻³ and the hole concentration in the second region 176 is in a range of 5E17 to 2E18 cm⁻³. If the concentration of the first dopant of the first region 172 is too high and the thickness of the first region 172 is larger than that of the second region 176, more parts within the second region 176 are likely to be depleted, which disadvantages generating the depletion area 118.

In the embodiment as discussed above, the first region 172 is doped with the first dopant, and the second region 176 is doped with the second dopant different from the first dopant. In certain embodiments, it is possible that the first region 172 also includes the second dopant. In certain embodiments, it is possible that the third region 174 includes any one of the first dopant and the second dopant owing to dopant diffusing, memory effect and redistribution of the dopants which are common seen in metal-organic chemical vapor deposition (MOCVD) growth. As discussed in the embodiment above, the impurities in the third region 174 are not intentionally introduced in. In certain embodiments, in a secondary ion mass spectrometry (SIMS) on the semiconductor junction structure 170, a concentration of the second dopant in the third region 174 can be not smaller than 1E17 cm⁻³, and a concentration of the first dopant in the third region 174 can be in an increasing trend in a range of 1E16 to 1E18 cm⁻³ along the growth direction (i.e. the thickness direction from the second region 176 toward the first region 172). For example, the concentration of the first dopant in the third region 174 is in an increasing trend from a concentration which is lower than 1E17 cm⁻³ to a concentration which is greater than 8E17 cm⁻³.

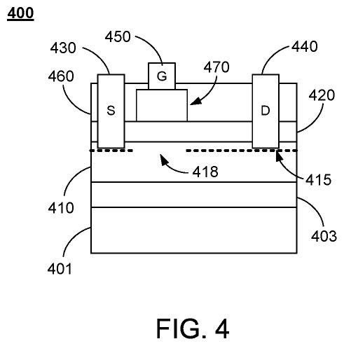

FIG. 4 shows a p-GaN E-HEMT 400 according to a comparative example. The difference between the p-GaN E-HEMT 400 and the E-HEMT 100 is that the p-GaN E-HEMT 400 includes a bulk p-GaN layer 470 and a gate electrode 450 formed on the p-GaN layer 470. The p-GaN layer 470 depletes a portion of the 2DEG 415 thereunder, such that a depletion area 418 exists in the 2DEG 415 right below the p-GaN layer 470. Compared to the comparative example, the E-HEMT 100 with the semiconductor junction structure 170 as shown in FIG. 1A may have a relatively higher threshold voltage Vₜₕ, which is greater than 2.5 V to get more stable E-HEMT characteristic. Since the threshold voltage Vₜₕ of the E-HEMT 100 is relatively high, there is no need to provide additional approaches for increasing threshold voltage Vₜₕ. For example, reducing the doping concentration (p-dopant) of the second region 176 to increasing the contact resistance, then the threshold voltage Vₜₕ is increased. Because the doping concentration of the second region 176 is reduced, then the thickness or the composition of the barrier layer has to be adjusted to decrease the 2DEG to keep the depletion area 418 exist. However, the decreased 2DEG will affect drain current I_{d}. of E-HEMT. The E-HEMT 100 can achieve a balance between a relatively higher threshold voltage Vₜₕ and a correspondingly higher drain current I_{d}. In addition, the gate electrode 150 is in direct contact with the first region 172, which is an n-type nitride semiconductor. Compared to the p-GaN E-HEMT 400 according to the comparative example as shown in FIG. 4, the first region 172 with n-type allows more manufacturing tolerance, which may not be as easily affected by the manufacturing processes for the gate electrode and the passivation layer.

Further, the semiconductor junction structure 170 is provided with a third region 174, which is unintentionally doped and may be a completely depleted region, thus effectively preventing from gate current I_{g} leakage. Moreover, due to the existence of the third region 174, the junction capacitance (which corresponds to the parasitic capacitance of the circuitry) may be further reduced in comparison to the conventional structure.

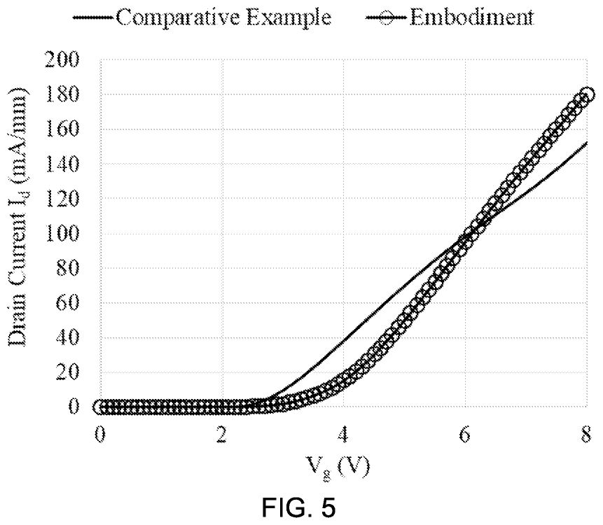

FIG. 5 shows the measurements of the gate voltage Vg and the drain current I_{d} of the E-HEMT 100 according to certain embodiments of the disclosure and the p-GaN E-HEMT 400 according to the comparative example. At a current density of 1 mA/mm of drain current I_{d}, the Vₜₕ of the E-HEMT 100 is 2.8 V, while that of the p-GaN E-HEMT 400 is 2.4 V. As shown in FIG. 5, compared to the p-GaN E-HEMT 400, the E-HEMT 100 according to certain embodiments of the disclosure may reach a higher threshold voltage Vₜₕ, and a larger drain current I_{d}, and the drain current I_{d} of the E-HEMT 100 raises significantly once being turned-on.

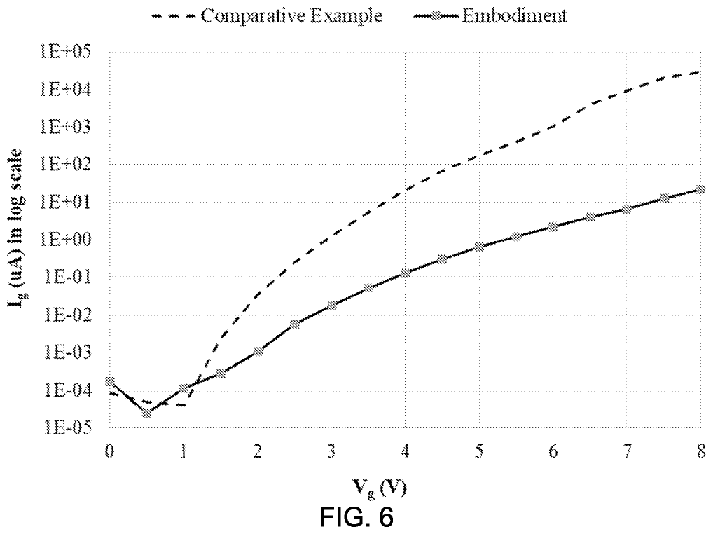

FIG. 6 shows the measurements of the gate voltage Vg and the gate current I_{g} of the E-HEMT 100 according to certain embodiments of the disclosure and the p-GaN E-HEMT 400 according to the comparative example. As shown in FIG. 6, compared to comparative example, there is a 3-order (i.e., about 103) reduction to the leakage of the gate current I_{g} for the E-HEMT 100.

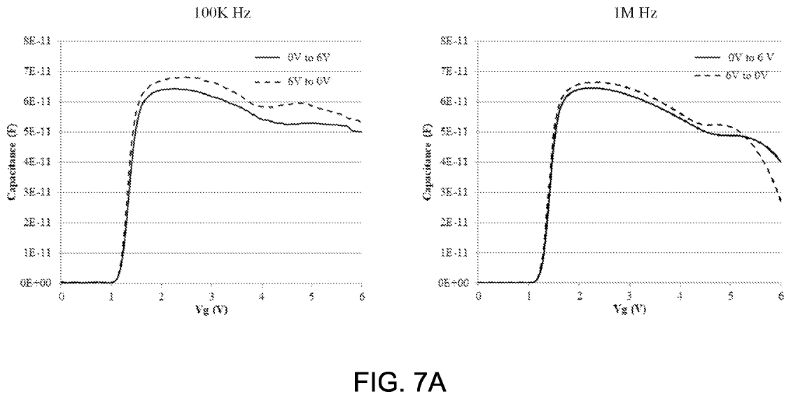

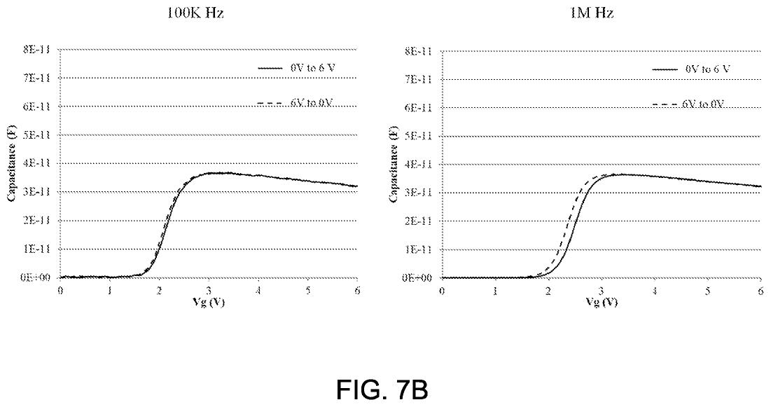

FIG. 7A shows the measurements of capacitance-voltage (C-V) curves of the p-GaN E-HEMT according to the comparative example where the frequency of the applied voltage are 100K Hz and 1M Hz, respectively. FIG. 7B shows the measurements of C-V curves of the E-HEMT 100 according to certain embodiments of the disclosure where the frequency of the applied voltage are 100K Hz and 1M Hz, respectively. Both FIG. 7A and FIG. 7B show the C-V curves with back and forth sweeping of the Vg.

As shown in FIG. 7A and FIG. 7B, regardless of the frequency, the junction capacitance of the E-HEMT 100 according to certain embodiments of the disclosure is significantly lower than that of the p-GaN e-HEMT, and the capacitance-to-voltage curves of the E-HEMT 100 are smoother and have less ripple, indicating that the E-HEMT 100 has a junction surface with fewer defects and lower current leakage. The interface states for a semiconductor structure can be characterized using frequency-dispersion in C-V curve measurements. A dispersion of the CV characteristics at different frequencies is related to the interface states. In general, larger dispersion indicates more interface states. As shown in FIG. 7A, the C-V characteristics of the comparative example exhibit relatively large dispersion indicating a relatively high density of interface states. In contrast, the identical curves for both sweep directions of the E-HEMT 100 show in FIG. 7B indicate relatively small frequency-dispersion, which shows a low density of interface states in the E-HEMT 100.

The E-HEMT 100 as discussed above may be used in a variety of applications. For example, the E-HEMT 100 may be used in or as a part of an electronic switch. Further, an electronic device may utilize the E-HEMT 100 as one or more switches therein.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to activate others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A semiconductor component, comprising:
a channel layer;
a barrier layer, formed on the channel layer;
a two-dimensional electron gas (2DEG), formed in the channel layer;
a gate electrode disposed on the barrier layer;
a semiconductor junction structure, disposed and sandwiched between the gate electrode and the barrier layer; and
a source electrode and a drain electrode, disposed at two sides of the gate electrode;
wherein the semiconductor junction structure comprises:
a first region doped with a first dopant and in direct contact with the gate electrode;
a second region doped with a second dopant different from the first dopant; and
a third region being unintentionally doped and sandwiched between the first region and the second region; and
wherein the semiconductor junction structure depletes a portion of the 2DEG thereunder.

2. The semiconductor component of claim 1, being an enhancement mode high-electron-mobility transistor (E-HEMT).

3. The semiconductor component of claim 1, having a threshold voltage greater than 2.5 V.

4. The semiconductor component of claim 1, wherein the third region forms a complete depletion region in the semiconductor junction structure.

5. The semiconductor component of claim 1, wherein a contact between the first region and the gate electrode is a Schottky contact or an Ohmic contact.

6. The semiconductor component of claim 1, wherein the semiconductor junction structure is an n-i-p junction structure, the first region is an n-type nitride region, and the second region is a p-type nitride region.

7. The semiconductor component of claim 6, wherein the first dopant comprises silicon (Si) or oxygen, and the second dopant includes magnesium (Mg), calcium, zinc beryllium or carbon.

8. The semiconductor component of claim 7, wherein the first region comprises the second dopant.

9. The semiconductor component of claim 6, wherein each of the first, second and third region comprises a nitride semiconductor material selected from a group consisting of GaN, AlGaN and AlN.

10. The semiconductor component of claim 1, wherein a thickness of the second region is greater than a thickness of the first region and a thickness of the third region.

11. The semiconductor component of claim 1, wherein a thickness of the first region is in a range of 5-100 nm.

12. The semiconductor component of claim 11, wherein the thickness of the first region is in a range of 20-30 nm.

13. The semiconductor component of claim 1, wherein a thickness of the second region is in a range of 50-200 nm.

14. The semiconductor component of claim 13, wherein the thickness of the second region is in a range of 55-75 nm.

15. The semiconductor component of claim 1, wherein a thickness of the third region is in a range of 1-50 nm.

16. The semiconductor component of claim 15, wherein the thickness of the third region is in a range of 5-15 nm.

17. The semiconductor component of claim 1, wherein a concentration of the first dopant of the first region is in a range of 5E16 to 5E19 cm⁻³, and a concentration of the second dopant of the second region is in a range of 1E18 to 1E20 cm⁻³.

18. The semiconductor component of claim 1, further comprising:
a passivation layer located between the gate electrode, the source electrode and the drain electrode, and covering the semiconductor junction structure and the barrier layer.

19. An electronic switch, comprising the semiconductor component of claim 1.

20. An electronic device, comprising at least one of the semiconductor component of claim 1.
